(19) United States
(12) Patent Application Publication
(10) Pub. No.: US 2009/0065779 A1
(43) Pub. Date: Mar. 12, 2009

(54) SEMICONDUCTOR DEVICE AND MANUFACTURING METHOD THEREOF

(75) Inventor: Kenichi KUSUMOTO, Tokyo (JP)

Correspondence Address: SCULLY SCOTT MURPHY & PRESSER, PC, 400 GARDEN CITY PLAZA, SUITE 300, GARDEN CITY, NY, 11530, US

(73) Assignee: ELPIDA MEMORY, INC., Tokyo (JP)

(21) Appl. No.: 12/207,152

(22) Filed: Sep. 9, 2008

(30) Foreign Application Priority Data
Sep. 10, 2007 (JP) 2007-234173

(51) Int. Cl. H01L 29/10; H01L 21/8238

(52) U.S. Cl. 257/66; 438/199; 257/E29.292

(57) ABSTRACT

A semiconductor device includes a silicon substrate; a gate insulation film formed on the silicon substrate; and a gate electrode formed on the gate insulation film; wherein the gate electrode has a first doped polysilicon film formed on the gate insulation film, and a second doped polysilicon film formed on the first doped polysilicon film; wherein the first doped polysilicon film includes first impurities; and wherein the second doped polysilicon film includes second impurities that has the opposite conductivity type from the first impurities.

### BACKGROUND OF THE INVENTION

1. Field of the Invention

The present invention relates to a semiconductor device and to a manufacturing method thereof, and particularly relates to a semiconductor device provided with a multilayer silicon gate and to a manufacturing method thereof.

2. Description of Related Art

In recent years, dual-gate CMOS have been gaining attention. A single-gate structure in which a polymetal gate obtained by layering a metal silicide film on an n⁺ polysilicon film is adopted for both the NMOSFET and PMOSFET is used in a regular CMOS. The single-gate structure can be manufactured with a simple process, but a miniaturized device is difficult to manufacture because a short-channel effect readily occurs in the PMOSFET.

In contrast, in a dual-gate CMOS, a polymetal gate obtained by layering n⁺ polysilicon and metal silicide is used in the NMOSFET, and a polymetal gate obtained by layering p⁺ polysilicon and metal silicide is used in the PMOSFET. The short channel effect is therefore small and a CMOS with a large driving power can be achieved.

FIG. 13 is a schematic cross-sectional view showing some of the manufacturing steps of a dual-gate semiconductor device according to a background art.

To form a dual gate, a gate insulation film 52 composed of SiON is first formed on a silicon substrate 51, and a non-doped amorphous silicon film 53 for a gate electrode is then formed, as shown in FIG. 13. P-type impurities or n-type impurities are subsequently introduced into the non-doped amorphous silicon film 53. Phosphorus (P), arsenic (As), or another n-type impurity ions are implanted at this time in the case of an NMOS; and boron (B), boron difluoride (BF₂), or another p-type impurity ions are implanted at this time in the case of a PMOS. That is, the dopants are selected in accordance with the conductivity type of the gate electrode. Tungsten silicide (WSi) or another metal silicide film 54 is then formed, annealing or another high-temperature thermal load step is further performed in order to activate the impurities, and the dopants are diffused in the amorphous silicon film 53.

The so-called problem of boron penetration, in which the boron (B) doped into the amorphous silicon film 53 in the formation area of a PMOSFET passes through the gate insulation film 52 and reaches the silicon substrate 51 during the high-temperature thermal loading, is known to occur in the method for manufacturing the semiconductor device according to the background art as described above. Boron penetration creates the problem that the threshold voltage (Vth) of the PMOSFET fluctuates dramatically and the transistor characteristics are adversely affected.

To solve the problem of boron penetration, it is proposed for example, in Japanese Laid-open Patent Publication No. 2000-114395, to use a CMOSFET in which p⁺ impurities are introduced into the polysilicon of the gate electrodes of the NMOSFET and PMOSFET to adopt a p⁺ single gate, and in which the gate insulation film is formed using a silicon oxynitride film (SiON) that includes nitrogen in a maximum concentration range of from 1×10²⁰/cm³ or greater to 1×10²²/cm³ or less.

### SUMMARY

The manufacturing method of the semiconductor device according to the background art presents a problem in that penetration of the gate insulation film by boron (B) causes the threshold voltage (Vth) to become nonuniform, as mentioned above. Another problem is that the impurities in the polysilicon film are depleted and the transistor characteristics are adversely affected by the absorption of the impurities in the polysilicon film by the metal silicide film and by the outflow of the impurities outside the polysilicon film during the high-temperature heat treatment.

The present invention seeks to solve one or more of the above problems, or to improve upon those problems at least in part.

In one embodiment, there is provided a semiconductor device that includes a silicon substrate, a gate insulation film formed on the silicon substrate, and a gate electrode formed on the gate insulation film, wherein the gate electrode has a first doped polysilicon film formed on the gate insulation film, and a second doped polysilicon film formed on the first doped polysilicon film; wherein the first doped polysilicon film includes a first impurities; and wherein the second doped polysilicon film includes a second impurities that has the opposite conductivity type from the first impurities.

According to the present invention, the first doped polysilicon film is interposed between the second doped polysilicon film and the gate insulation film, and the conductivity type of the impurities in the second doped polysilicon film is different from that of the first doped polysilicon film. Therefore, excessive diffusion of the impurities of the second doped polysilicon film is reduced in a step for diffusing the impurities within the polysilicon or in a subsequent high-temperature thermal load step. It is therefore possible to prevent the Vth from being caused to fluctuate by the impurities penetrating the gate insulation film, or the impurities in the polysilicon from being depleted.

In another embodiment, there is provided a manufacturing method of a semiconductor device that includes forming a gate insulation film on a silicon substrate; forming a gate electrode on the gate insulation film; and applying thermal load to the entire silicon substrate, wherein the forming the gate electrode includes forming a first doped amorphous silicon film on the gate insulation film, the first doped amorphous silicon film being doped with first impurities, forming a non-doped amorphous silicon film on the first doped amorphous silicon film, and ion-implanting second impurities having a conductivity type different from that of the first impurities into the non-doped amorphous silicon film.

According to the present invention, the first doped amorphous silicon film is interposed between the non-doped amorphous silicon film and the gate insulation film, and the conductivity type of the impurities in the first doped amorphous silicon film is different from the conductivity type of the impurities implanted as ions into the non-doped amorphous silicon film. It is therefore possible to prevent excessive diffusion of the second impurities introduced into the non-doped polysilicon film in a thermal load step. Accordingly, the impurities can be prevented from penetrating through the gate insulation film, and the impurities in the polysilicon film can be prevented from being depleted by the absorption of the impurities by the metal silicide film.

In still another embodiment, there is provided a method manufacturing of a semiconductor device that includes forming a gate insulation film in an NMOS channel region and a PMOS channel region on a silicon substrate; forming a gate electrode on the gate insulation film; and applying thermal load to the entire silicon substrate; wherein forming the gate insulation film includes forming a first doped amorphous silicon film on the gate insulation film, first doped amorphous silicon film being doped with n-type impurities, forming a non-doped amorphous silicon film on the first doped amorphous silicon film, and ion-implanting p-type impurities into the non-doped amorphous silicon film in the PMOS channel region and n-type impurities into the non-doped amorphous silicon film in the NMOS channel region.

According to the present invention, it is possible to provide a high-performance semiconductor device wherein the impurities concentration profile within the polysilicon film can be improved and the nonuniformity of the threshold voltage can be reduced.

The present invention can also provide a method for manufacturing a semiconductor device in which the second impurities (for example, boron (B)) can be prevented from penetrating through the gate insulation film, and the impurities in a polysilicon film can be prevented from being depleted by the absorption of the impurities by a metal silicide film.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a schematic cross-sectional view showing the structure of the semiconductor device 100 according to a preferred embodiment of the present invention;

FIG. 2 is a cross section of one process (formation of an NMOS channel region 10A and PMOS channel region 10B) of a manufacturing method of a semiconductor device 100 according to a preferred embodiment of the present invention;

FIG. 3 is a cross section of one process (formation of a gate insulation film 13) of the manufacturing method of the semiconductor device 100 according to a preferred embodiment of the present invention;

FIG. 4 is a cross section of one process (formation of a first doped amorphous silicon film 31a) of the manufacturing method of the semiconductor device 100 according to a preferred embodiment of the present invention;

FIG. 5 is a cross section of one process (formation of a non-doped amorphous silicon film 31b) of the manufacturing method of the semiconductor device 100 according to a preferred embodiment of the present invention;

FIG. 6 is a cross section of one process (formation of a second doped amorphous silicon film 31c) of the manufacturing method of the semiconductor device 100 according to a preferred embodiment of the present invention;

FIG. 7 is a cross section of one process (ion-implantation of Phosphorus (P⁺) ions into the NMOS channel region 10A) of the manufacturing method of the semiconductor device 100 according to a preferred embodiment of the present invention;

FIG. 8 is a cross section of one process (ion-implantation of Boron (B⁺) ions into the PMOS channel region 10B) of the manufacturing method of the semiconductor device 100 according to a preferred embodiment of the present invention;

FIG. 9 is a cross section of one process (formation of a metal silicide multilayer film 22) of the manufacturing method of the semiconductor device 100 according to a preferred embodiment of the present invention;

FIG. 10 is a cross section of one process (formation of a gate electrode 14 and a gate cap insulation film 15 by patterning) of the manufacturing method of the semiconductor device 100 according to a preferred embodiment of the present invention;

FIG. 11 is a cross section of one process (formation of first and second diffusion layers 17 and 18) of the manufacturing method of the semiconductor device 100 according to a preferred embodiment of the present invention;

FIG. 12 is a cross section of one process (applying of high-temperature thermal load) of the manufacturing method of the semiconductor device 100 according to a preferred embodiment of the present invention; and

FIG. 13 is a schematic cross-sectional view showing some of the manufacturing steps of a dual-gate semiconductor device according to a background art.

### DESCRIPTION OF THE PREFERRED EMBODIMENTS

The preferred embodiments of the present invention will be described in detail below with reference to the accompanying drawings.

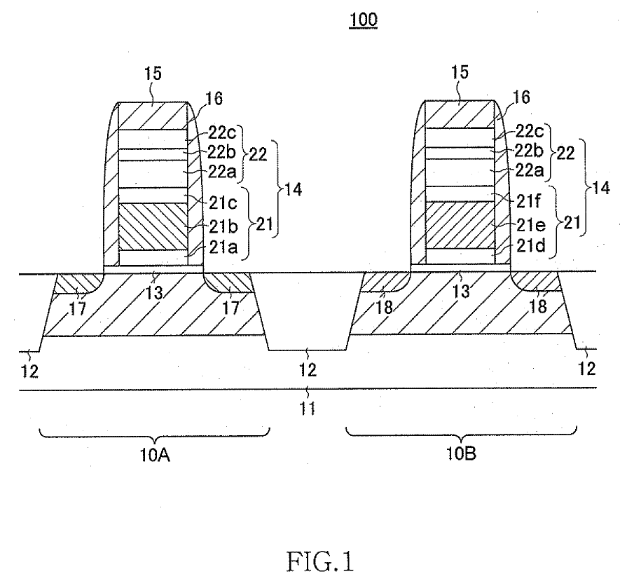

FIG. 1 is a schematic cross-sectional view showing the structure of the semiconductor device 100 according to a preferred embodiment of the present invention.

The semiconductor device 100 is a dual-gate CMOS in which a NMOSFET 10A having an n⁺ polysilicon gate and a PMOSFET 10B having a p⁺ polysilicon gate are formed on the same substrate, as shown in FIG. 1. The NMOSFET 10A and the PMOSFET 10B are both provided with a gate insulation film 13 formed on a silicon substrate 11, a gate electrode 14 formed on the gate insulation film 13, a gate cap insulation film 15 that covers the top surface of the gate electrode 14, sidewall insulation films 16 that covers side surfaces of the gate electrode 14, first diffusion layers 17 that serve as source/drain regions for the NMOSFET 10A, and second diffusion layers 18 that serve as source/drain regions for the PMOSFET 10B.

The gate electrode 14 has a polymetal gate structure and is provided with a polysilicon multilayer film 21 having a three-layer structure, and a metal silicide multilayer film 22 formed on the polysilicon multilayer film 21. The structure of the metal silicide multilayer film 22 is the same for both the NMOSFET and the PMOSFET, and is one in which a tungsten silicide (WSi) film 22a, tungsten nitride (WN) film 22b, and tungsten (W) film 22c are layered in sequence. In contrast, the structure of the polysilicon multilayer film 21 differs between the NMOSFET 10A and the PMOSFET 10B.

The polysilicon multilayer film 21 of the NMOSFET 10A has a three-layer structure wherein first through third doped polysilicon films 21a, 21b, 21c doped with phosphorus (P) or other n-type impurities are layered in sequence. The concentration of the n-type impurities in the first and third doped polysilicon films 21a and 21c is less than the concentration of the n-type impurities in the second doped polysilicon film. The three-layer structure is formed in conjunction with the formation of the polysilicon multilayer film 21 of the PMOSFET 10B into a three-layer structure, and the three-layer structure itself does not hold a special meaning for the NMOSFET 10A. The polysilicon multilayer film 21 of the NMOSFET 10A functions as an n⁺ polysilicon gate because each layer of the polysilicon multilayer film 21 is thus doped with n-type impurities.

The polysilicon film 21 of the PMOSFET 10B, on the other hand, has a three-layer structure wherein a first doped polysilicon film 21d doped with phosphorus (P⁺) or other n-type impurities, a second doped polysilicon film 21e doped with boron (B⁺) or other p-type impurities, and a third doped polysilicon film 21f doped with the same n-type impurities as the first doped polysilicon film 21d are layered in sequence.

The first and third doped polysilicon films 21d and 21f serve to prevent excessive diffusion of the p-type impurities of the second doped polysilicon film 21e in the PMOSFET 10B. The concentration of the p-type impurities must be sufficiently higher than that of the n-type impurities in order to configure the gate electrode 14 of the PMOSFET 10B as a p⁺ polysilicon gate. Therefore, the concentration of the n-type impurities in the first and third doped polysilicon films 21d and 21f is set at a sufficiently low level as long as this role can be fulfilled. In contrast, p-type impurities whose concentration is sufficiently high to allow the polysilicon multilayer film 21 to actually function as a p⁺ gate is distributed in the second doped polysilicon film 21e.

The polysilicon multilayer film 21 of the PMOSFET 10B cannot have an NPN junction, as in a bipolar transistor. This is because, the resistance increases and the performance of the gate decreases in an NPN junction structure. Therefore, it is possible to adopt an arrangement in which n-type impurities and p-type impurities are mixed with each other and the concentration of the p-type impurities in set higher than the concentration of the n-type impurities in the entire polysilicon multilayer film 21, and this is used as a p⁺ polysilicon gate in the various high-temperature thermal load steps generally present in the subsequent manufacturing steps (i.e., DRAM manufacturing steps). Simple mixing, while easy to accomplish, causes the impurities to escape to the outside. Therefore, the diffusion of impurities is controlled by adopting a sandwich structure as in the present invention.

Next, a method for manufacturing a semiconductor device 100 will be described in detail.

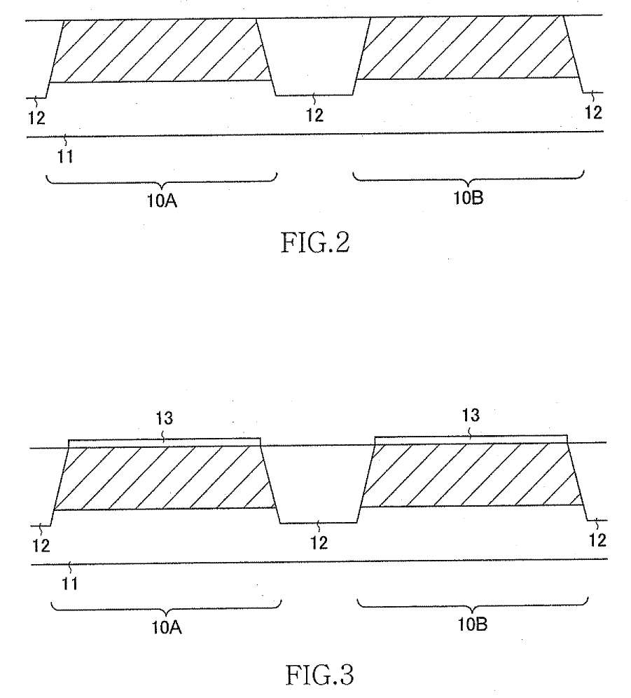

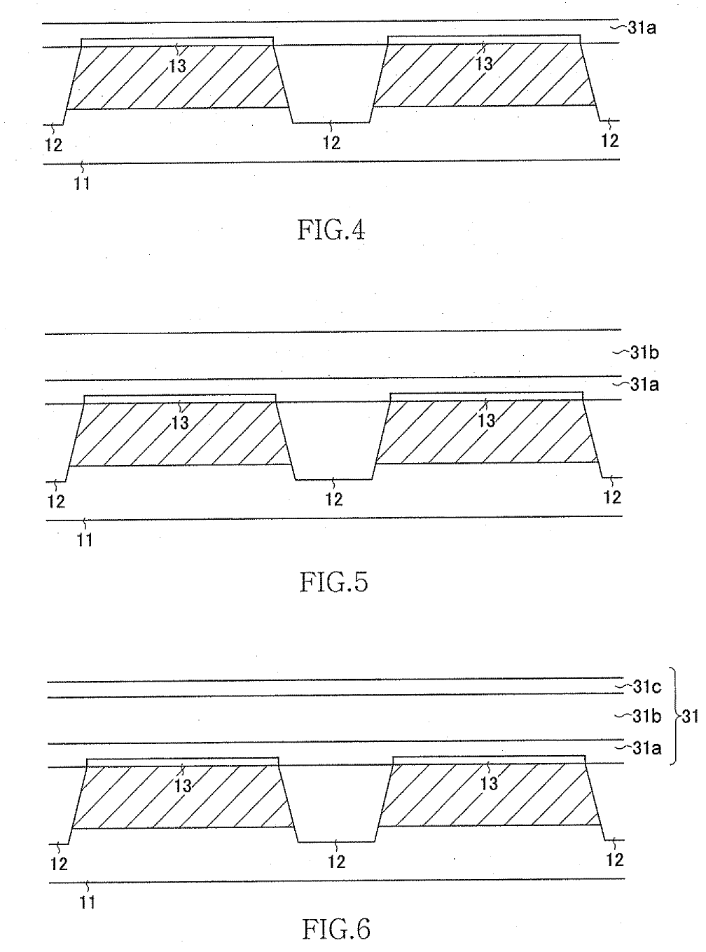

FIGS. 2 to 11 are schematic cross-sectional views showing the manufacturing method for a semiconductor device 100 according to a preferred embodiment of the present invention.

In the manufacturing of the semiconductor device 100, first element separation regions 12 composed of field oxide films are formed on the silicon substrate 11 by the STI method, and active regions separated from each other by the element separation region 12 are formed, as shown in FIG. 2. In one of the active regions, impurity ions are subsequently implanted in order to form a P well, impurity ions are implanted in order to form a buried layer aimed at preventing the transistor from being punched through, and impurity ions are implanted in order to adjust the threshold voltage Vth, forming an NMOS channel region 10A. In the other active region, impurity ions are also implanted in order to form an N well, impurity ions are implanted in order to form a buried layer aimed at preventing the transistor from being punched through, and impurity ions are implanted in order to adjust the threshold voltage Vth, forming a PMOS channel region 10B.

A gate insulation film 13 is subsequently formed in both the NMOS channel region 10A and the PMOS channel region 10B, as shown in FIG. 3. A silicon oxide film (SiO₂) having a thickness of about 5 nm is first formed by thermal oxidation during the formation of the gate insulation film 13. A heat treatment is then performed for about 60 seconds in an nitriding atmosphere of about 900° C., and the silicon oxide film is nitrided to complete the gate insulation film 13 composed of a silicon oxynitride film (SiON).

An amorphous silicon multilayer film 31 is subsequently formed on the gate insulation film 13. The amorphous silicon multilayer film 31 is formed using the steps shown below.

A first doped amorphous silicon film 31a doped with phosphorus (P) or other n-type impurities are first formed on the gate insulation film 13. This film can be formed by an LPCVD (Low-Pressured Chemical Vapor Deposition) method wherein silane gas (SiH₄) is used as the raw material gas, and, in particular, may be formed by a so-called “in-situ” method wherein a doped amorphous silicon film is deposited while the raw material gas for the phosphorus doping is introduced. The first doped amorphous silicon film 31a preferably has a thickness of about 10 to 50 nm.

A non-doped amorphous silicon film 31b is subsequently formed on the first doped amorphous silicon film 31a, as shown in FIG. 5. This film can also be formed by the LPCVD method wherein silane gas (SiH₄) is used as the raw material gas, and the film formation steps from the first doped amorphous silicon film 31a to the non-doped amorphous silicon film 31b can be performed continuously within the same chamber by interrupting the introduction of the raw material gas for the phosphorus doping. The non-doped amorphous silicon film 31b preferably has a thickness of about 10 to 200 nm.

A second doped amorphous silicon film 31c doped with phosphorus (P) or other n-type impurities are subsequently formed on the non-doped amorphous silicon film 31b, as shown in FIG. 6. This film can also be formed by the LPCVD method wherein silane gas (SiH₄) is used as the raw material gas, and the film formation steps from the non-doped amorphous silicon film 31b to the second doped amorphous silicon film 31c can be performed continuously within the same chamber by resuming the introduction of the raw material gas for the phosphorus doping. The second doped amorphous silicon film 31c preferably has a thickness of about 10 to 50 nm.

Phosphorus (P⁺) and boron (B⁺) ions are subsequently implanted into the non-doped amorphous silicon film 31b in the NMOS channel region 10A and into the non-doped amorphous silicon film 31b in the PMOS channel region 10b, respectively. This step is divided into two ion implantation steps.

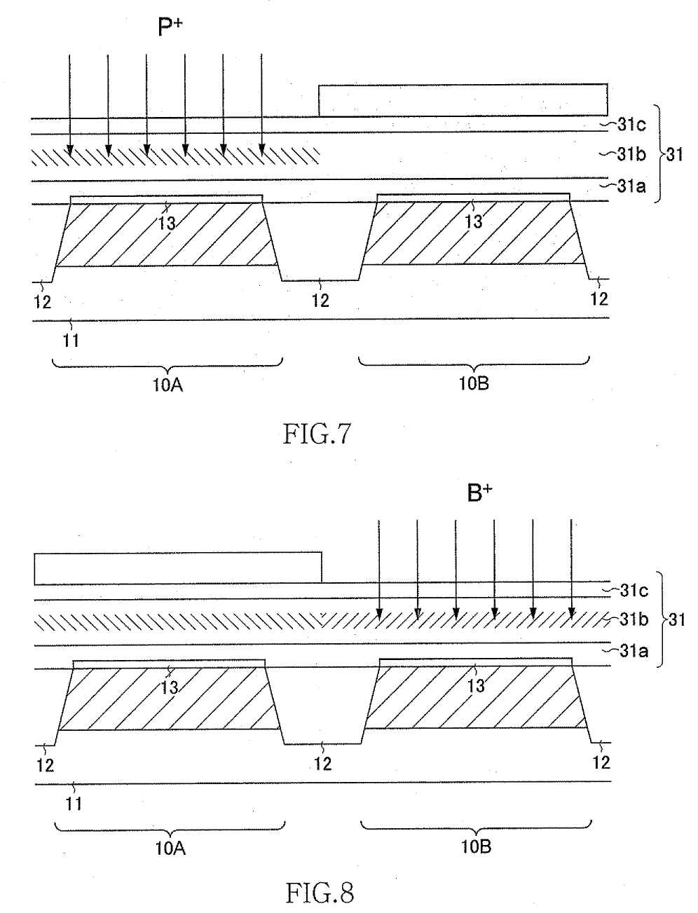

Phosphorus (P⁺) ions are first implanted into the non-doped amorphous silicon film 31b in the NMOS channel region 10A while the PMOS channel region 10B is masked, as shown in FIG. 7. The corresponding implantation energy is preferably about 5 to 30 keV, and the irradiation dose is 1×10¹⁴ cm⁻² to 5×10¹⁵ cm⁻². The entire amorphous silicon in the NMOS channel region 10A is thus made into an n⁺ silicon gate by introducing highly concentrated phosphorus (P⁺) into the non-doped amorphous silicon film 31b.

Boron (B⁺) ions are subsequently implanted into the non-doped amorphous silicon film 31b in the PMOS channel region 10B while the NMOS channel region 10A is masked, as shown in FIG. 8. The corresponding implantation energy is preferably about 1 to 20 keV, and the irradiation doze is 1×10¹⁴ cm⁻² to 1×10¹⁶ cm⁻². The entire amorphous silicon in the PMOS channel region 10B is made into a p⁺ gate because the boron concentration of the amorphous silicon film is increased by the bouncing back of boron (B⁺) in the amorphous silicon film that contains phosphorus (P).

Furthermore, the order of the ion implantation steps is not particularly limited, and either the PMOS channel region 10B or the NMOS channel region 10A may be implanted first.

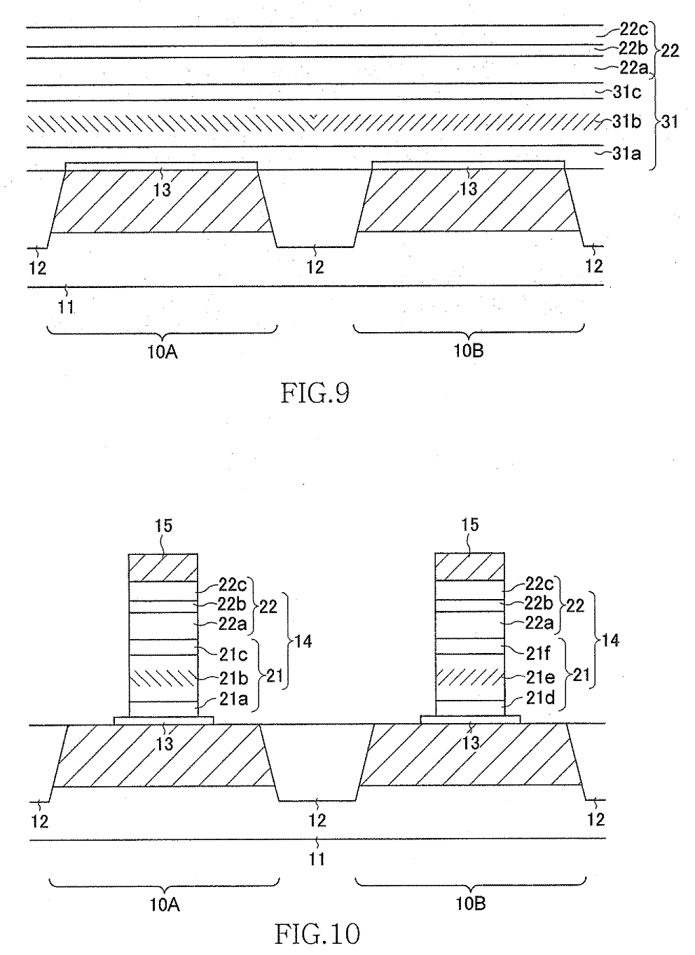

A metal silicide multilayer film 22 is subsequently formed on the amorphous silicon multilayer film 31, as shown in FIG. 9. In the present embodiment, a tungsten silicide (WSi) film 22a, tungsten nitride film (WN) 22b, and tungsten film (W) 22c are formed in sequence. It is possible, for example, to form the tungsten silicide film 22a by using tungsten hexafluoride (WF₆) gas and dichlorosilane (SiCl₂H₂) gas as the raw material gases and by using the LPCVD method under temperature conditions of 580° C. The tungsten silicide film 22a preferably has a thickness of about 1 to 20 nm. The tungsten nitride film 22b can be formed by sputtering and preferably has a thickness of 10 to 20 nm. The tungsten film 22c can be formed by sputtering and preferably has a thickness of 50 to 100 nm.

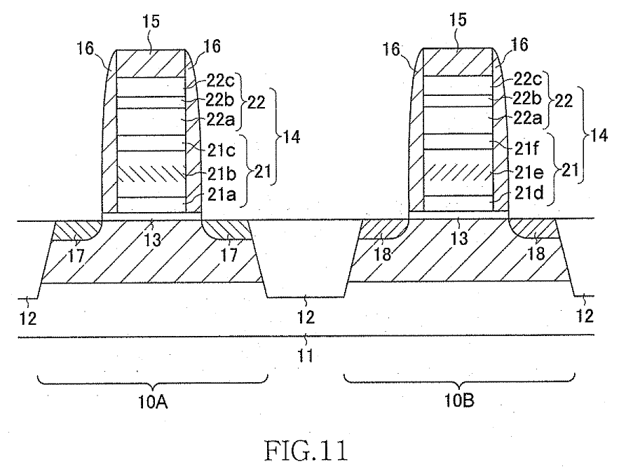

A silicon oxide film having a thickness of about 30 nm is subsequently formed on the metal silicide multilayer film 22; the polysilicon multilayer film 31, metal silicide multilayer film 22, and silicon oxide film are then patterned by using photolithography and etching; and gate electrodes 14 and gate cap insulation films 15 are formed, as shown in FIG. 10. A silicon oxide film having a thickness of about 30 nm is further formed across the entire surface of the substrate, and the film is then etched back, whereby sidewall insulation films 16 are formed on side surfaces of each gate electrodes 14, as shown in FIG. 11.

First diffusion layers 17 that serve as source/drain regions on the NMOSFET side, and second diffusion layers 18 that serve as source/drain regions on the PMOSFET side are then sequentially formed by a well-known method. The semiconductor device 100 provided with a dual-gate CMOS transistor is completed by the steps mentioned above.

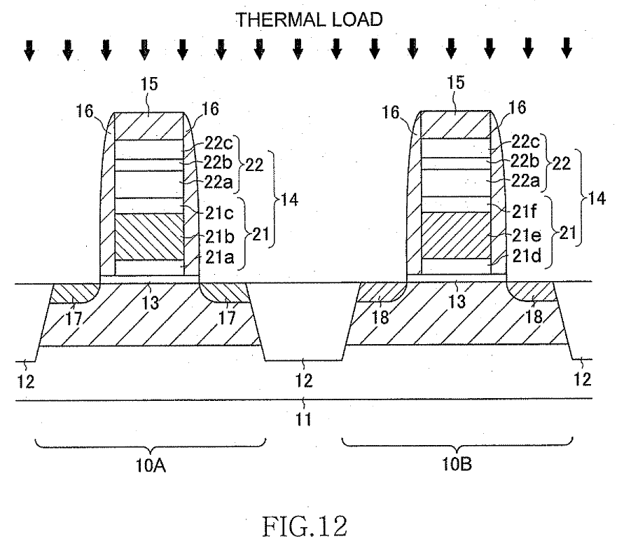

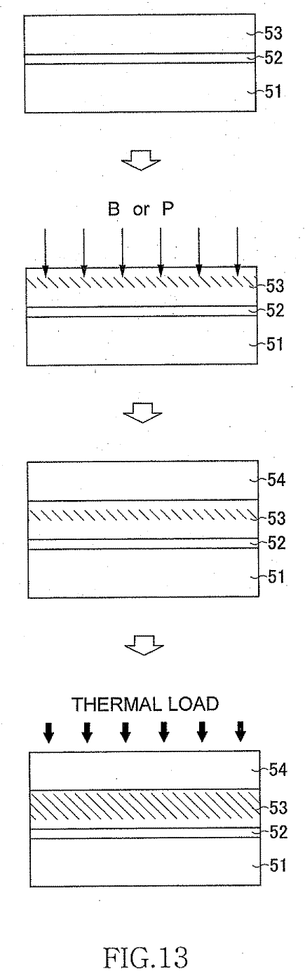

Furthermore, the phosphorus (P⁺) and boron (B⁺) of the amorphous silicon multilayer film 21 are diffused by subjecting the semiconductor device 100 to the various high-temperature thermal load steps generally present in the subsequent manufacturing steps (i.e., the DRAM manufacturing steps). When, however, different impurities are present at the same time, each of the impurities reduces the diffusion of the other. Therefore, the implanted dopant (boron) readily diffuses in the non-doped amorphous silicon film and has difficulty diffusing in the phosphorus (P⁺)-doped amorphous silicon film, as shown in FIG. 12. That is, the excessive diffusion of boron (B⁺) is reduced on the PMOSFET side because the top and bottom of the non-doped amorphous silicon film 31b are sandwiched between the first and second phosphorus-doped amorphous silicon films, as shown in FIG. 6. It is therefore possible to reduce penetration of boron (B) into the gate insulation film 13 and to reduce the absorption of the boron (B⁺) in the polysilicon film by the tungsten silicide film. Amorphous silicon is crystallized by the thermal load, and the amorphous silicon is converted to polysilicon.

In the manufacturing method of the semiconductor device 100 according to the present embodiment, the first and third amorphous silicon films are formed on the gate insulation film 13, the conductivity type of the impurities in the first and third amorphous silicon films is made to differ from that of the impurities introduced into the second amorphous silicon film sandwiched between the two, and the phenomenon of the different impurities reducing the diffusion of each other is utilized, making it possible to reduce the outflow of the impurities in the second layer to the outside.

It is apparent that the present invention is not limited to the above embodiments, but may be modified and changed without departing from the scope and spirit of the invention.

For example, phosphorus (P) or other n-type impurities are introduced into the first and third amorphous silicon films of the NMOSFET in the embodiment described above, but the present invention is not limited to such a structure, and it is acceptable to use a doped amorphous silicon film with boron (B) or other p-type impurities introduced into the first and third layer, and to implant ions of phosphorus (P⁺) or other n-type impurities into the non-doped amorphous silicon film 31b of the second layer. Phosphorus or other n-type impurities do not diffuse as easily as boron (B) or other p-type impurities; however, it is possible to prevent excessive diffusion of the n-type impurities implanted into the second layer by introducing p-type impurities into the first and third layers.

A polymetal gate is adopted and a metal silicide multilayer film 22 having a three-layer structure comprising tungsten silicide, tungsten nitride, and tungsten is used in the embodiment described above, but it is not necessary to adopt a polymetal gate structure in the present invention. The metal may also be dispensed with, and a structure composed of a single-layer film of tungsten silicide may be adopted.

A three-layer structure is used for the amorphous silicon film in the embodiment described above; however, it is possible to use a two-layer structure as well. That is, the problem of impurities absorption by the silicide layer does not occur in cases in which a metal silicide film is not formed on the top layer of the second amorphous silicon film, and the doped amorphous silicon film serving as a barrier layer may therefore be formed solely between the gate insulation film 13 and the non-doped amorphous silicon film 31b.

A mask is used to separate the boron (B⁺) and phosphorus (P⁺) both in the first ion implantation step wherein phosphorus (P⁺) ions are implanted into the non-doped amorphous silicon film 31b in the NMOS channel region 10A, and in the second ion implantation step wherein boron (B⁺) ions are implanted into the non-doped amorphous silicon film 31b in the PMOS channel region 10B in the embodiment described above, but the present invention is not limited to such ion implantation steps. For example, it is acceptable to implant phosphorus ions both into the NMOS channel region 10A and into the PMOS channel region 10B, then to mask only the NMOS channel region 10A, and to bounce back the boron having a higher concentration than the phosphorus of the PMOS channel region 10B. This ion implantation step allows boron and phosphorus each to be introduced into their prescribed regions in a single masking process. Making adjustments using the implantation depth is also acceptable.

What is claimed is:

1. A semiconductor device comprising:
a silicon substrate;
a gate insulation film formed on the silicon substrate; and
a gate electrode formed on the gate insulation film;
wherein the gate electrode has a first doped polysilicon film formed on the gate insulation film, and a second doped polysilicon film formed on the first doped polysilicon film; wherein the first doped polysilicon film includes first impurities; and
wherein the second doped polysilicon film includes second impurities that has the opposite conductivity type from the first impurities.

2. The semiconductor device as claimed claim 1,
wherein the gate electrode further comprises a third doped polysilicon film formed on the second doped polysilicon film, the third doped polysilicon film including the first impurities.

3. The semiconductor device as claimed claim 2, wherein the gate electrode further comprises a metal silicide film formed on the third doped polysilicon film.

4. The semiconductor device as claimed claim 2, wherein the concentration of the first impurities in the first and third doped polysilicon films is less than the concentration of the second impurities in the second doped polysilicon film.

5. The semiconductor device as claimed claim 2, wherein the first and third doped polysilicon films further include second impurities, and the concentration of the second impurities in the first and third doped polysilicon films is less than the concentration of the second impurities in the second doped polysilicon film.

6. The semiconductor device as claimed claim 1, wherein the first impurities is phosphorus (P), and the second impurities is boron (B).

7. A manufacturing method of a semiconductor device comprising:
forming a gate insulation film on a silicon substrate;
forming a gate electrode on the gate insulation film; and
applying thermal load to the entire silicon substrate, wherein the forming the gate electrode includes forming a first doped amorphous silicon film on the gate insulation film, the first doped amorphous silicon film being doped with first impurities, forming a non-doped amorphous silicon film on the first doped amorphous silicon film, and ion-implanting second impurities having a conductivity type different from that of the first impurities into the non-doped amorphous silicon film.

8. The manufacturing method of the semiconductor device as claimed in claim 7, wherein the forming the gate electrode further includes forming a second doped amorphous silicon film on the non-doped amorphous silicon film, the second doped amorphous silicon film being doped with the first impurities.

9. The manufacturing method of the semiconductor device as claimed in claim 8, wherein the forming the gate electrode further includes forming a metal silicide film on the second doped amorphous silicon film after the ion-implanting.

10. The manufacturing method of the semiconductor device as claimed in claim 7, wherein the first impurities are phosphorus (P), and the second impurities are boron (B).

11. A manufacturing method of a semiconductor device comprising:
forming a gate insulation film in an NMOS channel region and a PMOS channel region on a silicon substrate;
forming a gate electrode on the gate insulation film; and
applying thermal load to the entire silicon substrate; wherein forming the gate insulation film includes forming a first doped amorphous silicon film on the gate insulation film, first doped amorphous silicon film being doped with n-type impurities, forming a non-doped amorphous silicon film on the first doped amorphous silicon film, and ion-implanting p-type impurities into the non-doped amorphous silicon film in the PMOS channel region and n-type impurities into the non-doped amorphous silicon film in the NMOS channel region.

12. The manufacturing method of the semiconductor device as claimed in claim 11, wherein the forming the gate electrode further includes forming a second doped amorphous silicon film on the non-doped amorphous silicon film, the second doped amorphous silicon film being doped with the n-type impurities.

13. The manufacturing method of the semiconductor device as claimed in claim 11, wherein the forming the gate electrode further includes forming a metal silicide film on the second doped amorphous silicon film after the ion-implanting.

14. The manufacturing method of the semiconductor device as claimed in claim 11, wherein the ion-implanting includes first ion-implanting the p-type impurities into the non-doped amorphous silicon film in the PMOS channel region by using a first mask and second ion-implanting the n-type impurities into the non-doped amorphous silicon film in the NMOS channel region by using a second mask.

15. The manufacturing method of the semiconductor device as claimed in claim 11, wherein the first impurities is phosphorus (P), and the second impurities is boron (B).

16. The manufacturing method of the semiconductor device as claimed in claim 11, wherein the first and third doped polysilicon films include the p-type impurities, and in the applying thermal load, the concentration of the n-type impurities becomes lower than the concentration of the p-type impurities in the first and third doped polysilicon films and impurities diffusion is brought about so that a p-type gate electrode is formed in the PMOS channel region.
